(19) United States
(12) Patent Application Publication
(10) Pub. No.: US 2012/0070653 A1
(43) Pub. Date: Mar. 22, 2012

(54) COATED ARTICLE AND METHOD FOR MAKING THE SAME

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); CONG LI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/150,364

(22) Filed: Jun. 1, 2011

(30) Foreign Application Priority Data
Sep. 16, 2010 (CN) 201010283661.1

(51) Int. Cl. B32B 3/00; C23C 14/34; C23C 14/14

(52) U.S. Cl. 428/336; 428/221; 204/192.1; 204/192.15

(57) ABSTRACT

A coated article is provided. The coated article includes a substrate, and an anti-fingerprint layer formed on the substrate. The anti-fingerprint layer is a nano aluminum-oxygen-carbon-nitrogen (Al—O—C—N) layer. A method for making the coated article is also described there.

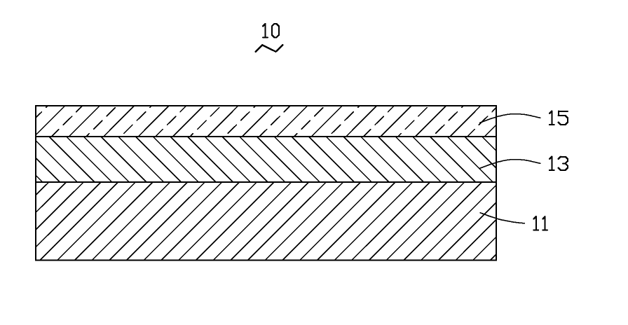

### CROSS-REFERENCE TO RELATED APPLICATIONS

This application is one of the three related co-pending U.S. patent applications listed below. All listed applications have the same assignee. The disclosure of each of the listed applications is incorporated by reference into all the other listed applications.

| Attorney | | |
|---|---|---|
| Docket No. | Title | Inventors |
| US 34428 | DEVICE HOUSING AND METHOD | HSIN-PEI |
| | FOR MAKING THE SAME | CHANG et al. |
| US 34432 | COATED ARTICLE AND METHOD | HSIN-PEI |
| | FOR MAKING THE SAME | CHANG et al. |
| US 34433 | COATED ARTICLE AND METHOD | HSIN-PEI |
| | FOR MAKING THE SAME | CHANG et al. |

### BACKGROUND

1. Technical Field

The present disclosure relates to coated articles, particularly to a coated article having an anti-fingerprint property and a method for making the coated article.

2. Description of Related Art

Many electronic housings are coated with anti-fingerprint layer. These anti-fingerprint layers are commonly painted with a paint containing organic anti-fingerprint substances. However, the print layers are thick (commonly 2 μm-4 μm) and not very effective. Furthermore, the paint may not be environmentally friendly.

Therefore, there is room for improvement within the art.

### BRIEF DESCRIPTION OF THE FIGURE

Many aspects of the coated article can be better understood with reference to the following FIGURE. The components in the FIGURE are not necessarily drawn to scale, the emphasis instead being placed upon clearly illustrating the principles of the coated article.

The FIGURE is a cross-sectional view of an exemplary embodiment of a coated article.

### DETAILED DESCRIPTION

The FIGURE shows a coated article 10 according to an exemplary embodiment. The coated article 10 includes a substrate 11, a transition layer 13 formed on a surface of the substrate 11, and an anti-fingerprint layer 15 formed on the transition layer 13.

The substrate 11 may be made of metal or non-metal material. The metal may be selected from a group consisting of stainless steel, aluminum, aluminum alloy, copper, copper alloy, and zinc. The non-metal material may be plastic, ceramic, glass, or polymer.

The transition layer 13 may be an aluminum layer formed by vacuum sputtering. The transition layer 13 may have a thickness of about 300 nm-400 nm. The transition layer 13 enhances the attachment of the anti-fingerprint layer 15 to the substrate 11.

The anti-fingerprint layer 15 may be a nano aluminum-oxygen-carbon-nitrogen (Al—O—C—N) layer formed by an environmentally friendly vacuum sputtering. The anti-fingerprint layer 15 only has a thickness of about 100 nm-200 nm, and has a transparent and glossy appearance. The anti-fingerprint layer 15 has a good anti-fingerprint property.

Moreover, the nitrogen contained in the anti-fingerprint layer 15 may further enhance the compactness and corrosion resistant properties of the anti-fingerprint layer 15.

It is to be understood that the transition layer 13 may be omitted if the bond between the anti-fingerprint layer 15 and the substrate 11 is strong enough.

A method for making the coated article 10 may include the following steps:

The substrate 11 is pretreated. The pre-treating process may include the following steps:

The substrate 11 is cleaned in an ultrasonic cleaning device (not shown) filled with ethanol or acetone.

The substrate 11 is plasma cleaned. The substrate 11 may be positioned in a plating chamber of a vacuum sputtering equipment (not shown). The plating chamber is fixed with an aluminum target therein. The plating chamber is then evacuated to about 4.0×10⁻³ Pa. Argon (Ar, having a purity of about 99.999%) may be used as a working gas and is injected into the chamber at a flow rate of about 300 standard-state cubic centimeter per minute (sccm) to 500 sccm. The substrate 11 may have a negative bias voltage at a range of −300 V-−500 V, so high-frequency voltage is produced in the plating chamber and the Ar is ionized to plasma. The plasma then strikes the surface of the substrate 11 to clean the surface of the substrate 11. Plasma cleaning the substrate 11 may take about 3 min-10 min. The plasma cleaning process will enhance the bond between the substrate 11 and the transition layer 13. The aluminum target is unaffected by the plasma cleaning process.

The transition layer 13 is vacuum sputtered on the pretreated substrate 11. Vacuum sputtering of the transition layer 13 is implemented in the plating chamber of the vacuum sputtering equipment. The inside of the plating chamber is heated to about 20° C.-300° C. Argon (Ar) may be used as a working gas and is injected into the chamber at a flow rate of about 300 sccm-500 sccm. Power is applied to the aluminum target fixed in the plating chamber, and the substrate 11 may have a negative bias voltage of about −100V-−300V to deposit the transition layer 13 on the substrate 11. Depositing of the transition layer 13 may take about 20 min-60 min.

The anti-fingerprint layer 15 is formed on the transition layer 13 by vacuum sputtering. Vacuum sputtering of the anti-fingerprint layer 15 is still implemented in the plating chamber of the vacuum sputtering equipment. The internal temperature of the plating chamber is maintained at about 20° C.-300° C. Argon (Ar) may be used as a working gas and is injected into the chamber at a flow rate of about 300 sccm-500 sccm. Nitrogen (N₂), acetylene (C₂H₂), and oxygen (O₂) may be used as reaction gases. The nitrogen may have a flow rate of about 5 sccm-70 sccm, the acetylene may have a flow rate of about 5 sccm-60 sccm, and the oxygen may have a flow rate of about 5 sccm-60 sccm. The substrate 11 may have a negative bias voltage to deposit the anti-fingerprint layer 15 on the transition layer 13. Depositing of the anti-fingerprint layer 15 may take about 20 min-60 min.

A glow discharge atomic emission spectrometry (GD-OES) test has been implemented to the coated article 10. The test indicates that the Al, O, C, and N elements of the anti-fingerprint layer 15 are evenly distributed in the anti-fingerprint layer 15.

The anti-fingerprint property of the anti-fingerprint layer 15 has been tested by using a dyne test pen (brand: ACCU; the place of production: U.S.A.). The test has indicated that the surface tension of the anti-fingerprint layer 15 is below 30 dynes, thus, the anti-fingerprint layer 15 has a good anti-fingerprint property.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A coated article, comprising:
a substrate; and
an anti-fingerprint layer formed on the substrate, the anti-fingerprint layer being a nano aluminum-oxygen-carbon-nitrogen layer.

2. The coated article as claimed in claim 1, wherein the anti-fingerprint layer has a thickness of about 100 nm-200 nm.

3. The coated article as claimed in claim 2, wherein the anti-fingerprint layer is formed by vacuum sputtering.

4. The coated article as claimed in claim 1, further comprising a transition layer formed between the substrate and the anti-fingerprint layer.

5. The coated article as claimed in claim 4, wherein the transition layer is an aluminum layer formed by vacuum sputtering.

6. The coated article as claimed in claim 5, wherein the transition layer has a thickness of about 300 nm-400 nm.

7. The coated article as claimed in claim 1, wherein the substrate is made of metal or non-metal material.

8. The coated article as claimed in claim 7, wherein the metal is selected from a group consisting of stainless steel, aluminum, aluminum alloy, copper, copper alloy, and zinc, the non-metal material is selected from a group consisting of plastic, ceramic, glass, or polymer.

9. A method for making a coated article, comprising:
providing a substrate; and
forming an anti-fingerprint layer on the substrate by vacuum sputtering, the anti-fingerprint layer being a nano aluminum-oxygen-carbon-nitrogen layer.

10. The method as claimed in claim 9, wherein vacuum sputtering the anti-fingerprint layer uses an aluminum target; uses nitrogen, acetylene, and oxygen as reaction gases, the nitrogen has a flow rate of about 5 sccm-70 sccm, the acetylene has a flow rate of about 5 sccm-60 sccm, the oxygen has a flow rate of about 5 sccm-60 sccm; uses argon as a working gas, the argon has a flow rate of about 300 sccm-500 sccm; vacuum sputtering the anti-fingerprint layer is at a temperature of about 20° C.-300° C.

11. The method as claimed in claim 10, wherein the substrate is biased with a negative bias voltage of about −100V-−300V during vacuum sputtering the anti-fingerprint layer.

12. The method as claimed in claim 9, further comprising a step of vacuum sputtering a transition layer on the substrate before forming the anti-fingerprint layer.

13. The method as claimed in claim 12, wherein vacuum sputtering the transition layer uses an aluminum target; uses argon as a working gas, the argon has a flow rate of about 300 sccm-500 sccm; vacuum sputtering the transition layer is at a temperature of about 20° C.-300° C.; vacuum sputtering the transition layer takes about 20 min-60 min.

14. The method as claimed in claim 13, wherein the substrate is biased with a negative bias voltage of about −100V-−300V during vacuum sputtering the transition layer.

15. The method as claimed in claim 12, further comprising a step of pre-treating the substrate before forming the transition layer.

16. The method as claimed in claim 15, wherein the pre-treating process comprising ultrasonically cleaning the substrate and plasma cleaning the substrate.

17. The method as claimed in claim 9, wherein the substrate is made of metal material or non-metal material.

18. The method as claimed in claim 17, wherein the metal is selected from a group consisting of stainless steel, aluminum, aluminum alloy, copper, copper alloy, and zinc, the non-metal material is selected from the group consisting of plastic, ceramic, glass, or polymer.
